(19) United States
(12) Patent Application Publication
(10) Pub. No.: US 2001/0006759 A1
(43) Pub. Date: Jul. 5, 2001

(54) RADIATION SENSITIVE COMPOSITIONS

(75) Inventors: CHARLES R. SHIPLEY JR., NEWTON, MA (US); JAMES G. SHELNUT, NORTHBORO, MA (US); WADE SONNENBERG, UPTON, MA (US)

Correspondence Address: PETER F CORLESS, P O BOX 556, MARLBOROUGH, MA, 01752

(73) Assignee: Charles R. Shipley Jr.

(21) Appl. No.: 09/149,318

(22) Filed: Sep. 8, 1998

(51) Int. Cl. G03F 7/027; G03F 7/028; G03F 7/033; G03F 7/038; G03F 7/09; G03F 7/30; G03F 7/40; C08J 3/24; B32B 25/16; B32B 27/16

(52) U.S. Cl. 430/280.1; 522/100; 522/109; 430/311; 430/277.1; 430/296; 430/330; 525/69; 525/332.3; 427/517; 427/506; 427/518; 427/521; 427/532

(57) ABSTRACT

Radiation sensitive compositions, processes for using the compositions, and articles of manufacture comprising the compositions. The compositions of the invention are use to form flexible coatings having a dielectric constant of 3 or less. The compositions comprise a resin binder and a polybutadiene that comprises one or more internal epoxide groups. In preferred aspect of the invention, the compositions of the invention further comprise a crosslinking agent capable of solvating the remaining constituents of the composition. The coatings are used for the manufacture of electronic and other devices.

### BACKGROUND OF THE INVENTION

1. Introduction

The invention relates to flexible, low dielectric constant coating compositions. More particularly, the invention relates to coating compositions that provide coatings exhibiting a low dielectric constant and substantial flexibility following cure. The invention also relates to processes and articles of manufacture that comprise such compositions.

2. Background Art

The need exists for new coating compositions that are flexible following cure and which exhibit a low dielectric constant, typically 3 or less, particularly for electronics-related applications. For example, a present trend in the printed wiring board industry is towards increasing the number of circuit layers in a board and decreasing the width of formed lines and spaces. Conventional multilayer printed circuit boards comprise glass cloth reinforced copper-clad plastic substrates that range in thickness from 4-8 mils for the insulative plastic alone. After etching desired circuitry configurations on a signal layer, the board innerlayers are separated from each other by an insulating layer and then laminated to form a multilayer board comprising circuitry, ground plane and power plane levels. Holes are drilled through the board stack and the hole walls plated to formed conductive interconnects between the multiple board layers. This manufacturing process poses notable problems such as drill wear, smear misregistration and hole size limitations, all inherent in such a drilled board approach. Also, circuit densification is curtailed by the presence of relatively large via apertures (typically 12-20 mil in diameter) which necessitate pads that consume additional board space.

A means to avoid such problems is a multilayer circuit board manufacturing process where board layers are formed sequentially using selective plating techniques, imaging of light sensitive materials to achieve fine line resolution and interconnections between circuits and separation of circuit layers from each other using a coating composition that has a low dielectric constant and which is flexible following cure. Such a manufacturing process has been described in U.S. Pat. No. 4,902,610, incorporated herein by reference. It would be desirable to have a new coating composition that has utility as a flexible, low dielectric constant material in such a sequential circuit board fabrication process.

An additional need for a low dielectric constant coating composition is in the silicon wafer fabrication industry where there is need to reduce the size of the conductive lines used to connect the silicon wafer with other electronic components to 0.25 microns or less. For these geometries, current materials are unsuitable due to their high dielectric constants which cause electronic interference between conductive lines at very small geometries. A means to avoid such problems would be to use organic coatings that have inherently low dielectric constant. Such materials need to withstand high temperatures of in excess of 250° C., have a low dielectric constant of 2.7 or less, have low moisture absorption below 0.5%, isotropic dielectric constant across and through the coating, a high Tg above 200° C., excellent adhesion to copper, aluminum, or silicon dioxide, low stress, and compatibility with CMP and Damascene processes.

Another application for a low dielectric flexible coating composition is as a soldermask or solder resist. These materials are compositions used to mask off a portion of a printed circuit board and prevent those areas from accepting solder during solder processing. See Coombs, Printed Circuits Handbook, ch. 16, McGraw Hill (3rd ed., 1988), incorporated herein by reference. Known commercially available photoimageable soldermasks form a relatively brittle coating layer upon curing. A brittle soldermask coating can pose notable problems. For example, a brittle coating may be degraded during processing and prior to application of solder, thereby resulting in complete rejection of the board or requiring the removal of the cured composition and board reprocessing.

In addition to the above, flexible, low dielectric coatings are needed for flexible circuit manufacture. Flexible circuits have been defined as a patterned arrangement of printed circuits and components utilizing flexible base materials with or without non-photoimageable flexible cover layers or “coats”. See Coombs, Printed Circuits Handbook, ch. 35, McGraw Hill (3rd ed., 1988), incorporated herein by reference. For typical applications, only two types of cover coats are used—non-photoimageable polyimide and polyester. Other non-photoimageable cover coats also are used such as Teflon and Ultem, but their utility are typically limited to specialized applications. Current fabrication methods of a flexible circuit includes prepunching the cover coats with holes for solder pads and then carefully aligning the cover coat on the base material. Current industry demands call for more apertures in the cover coat layer, more precise registration of the apertures with the base layer and good bonding of the cover coat to the underlying base layer.

Multichip modules have gained increased use, particularly in advanced computer systems. See Technology Update (9108, Multichip Modules and Their Impact on Board Makers,” RP428-RT, BPA (Technology and Management) LTD (September 1991); and J. Balde, “Multichip Modules: The Construction in Use Today”, Proceedings NEPCON-West, 965-974 (February 1990), both incorporated herein by reference. Materials of construction of multichip modules include for example aluminum nitride, silicon carbide, alumina coated copper-tungsten, silicon wafers with external mechanical support and CVD diamond coated ceramics. Manufacture of devices comprising such substrate materials require low dielectric coating compositions with improved CTE characteristics at operation temperatures (e.g., a CTE of less than 30 ppm at 200° C.) and ever lower dielectric constants, including dielectric constants of 3 or less. It thus would be desirable to have coating compositions that provide such performance characteristics suitable for use in MCM manufacturing processes.

### SUMMARY OF THE INVENTION

The present invention provides novel coating compositions capable of providing a cured coating layer that, following cure, exhibits substantial flexibility with a dielectric constant of 3 or less, preferably 2.5 or less. In general, a composition of the invention comprises a resin binder, a reactive polybutadiene that comprises one or more internal epoxide groups, and optionally, if a photoimageable composition is desired, a radiation sensitive component. As used herein, the term “polybutadiene” refers to a material that is obtainable from the reaction of a butadiene monomer, oligomer or polymer. For example, the term “polybutadiene” includes a butadiene dimer. As used herein, the term “polybutadiene that contains one or more internal epoxide groups” refers to a polybutadiene that comprises one or more oxirane oxygens bonded to carbons within the polybutadiene backbone, rather than an epoxide group pendant to the butadiene backbone or an epoxide group that is a bonded to a terminal carbon of the butadiene chain. It is also understood that a polybutadiene that comprises one or more internal epoxide groups also suitably may comprise one or more pendant and/or terminal epoxide groups. Preferably the epoxidized polybutadiene is miscible with the other components of the composition both before and after curing of a coating layer of the composition.

While substantially non-reactive resin binders are suitably employed in the compositions of the invention, preferably the resin binder is a reactive polymer that can undergo thermal or photoactivated crosslinking with one or more components of the composition. Preferably a composition of the invention further comprises one or more one crosslinking agents and a photoactive or thermal initiator system in addition to the epoxidized polybutadiene component.

A variety of resin binders can be employed. Suitable reactive resins are those that contain a functional group that can react with one or more other components of the composition, for example a reactive hydrogen containing resin. Generally preferred reactive resins are phenolic and alicyclic resins. With respect to the crosslinker component, a variety of crosslinking agents may be employed. Preferred crosslinkers include an epoxy-containing material and amine-based crosslinkers. Such crosslinkers, in the presence of a suitable catalyst, will cure to form a polymerized network with the reactive resin binder and internally epoxidized polybutadiene, for example a cured terpolymeric mixture where a single crosslinker is employed or a cured tetrapolymeric mixture where two different types of crosslinkers are employed. The curing catalyst, if present, can comprise a compound that generates acid or generates base upon exposure to activating radiation or heat or both.

In a preferred embodiment of the invention, the coating compositions of the invention are free of solvents that require removal, such as by baking, to form a dry coating. In this respect, low molecular weight reactive constituents of the coating composition may function as solubilizing agents for the remaining coating composition components. Since the solvating constituents are reactive, they participate in the curing reaction a bake step to remove solvents is not required to form a dry coating layer. The avoidance of conventional non-reactive solvents eliminates the steps of soft bake and solvent recovery during the processing sequence.

The compositions of the invention have utility in a variety of applications. Hence, the invention includes processes employing the compositions of the invention, including processes for the manufacture of printed circuit boards, additive printed circuits, multilayer printed circuits, high density printed circuits, flexible circuits, surface mount devices, multichip modules, insulating dielectric chip materials, and other articles. The invention further provides novel articles of manufacture comprising substrates coated with the compositions of the invention.

The terms “crosslink”, “crosslinking” and other such terms used herein refer to any reaction of one or more of the components of a composition of the invention that results in reduced solubility of the composition in processing chemicals.

### DETAILED DESCRIPTION OF THE INVENTION

A composition of the invention in general comprises a resin binder, an epoxidized polybutadiene that contains internal epoxide groups, preferably a crosslinking agent component, and a curing catalyst which in one embodiment of the invention, comprises a radiation sensitive component.

The resin binder component may comprise a nonreactive resin or, preferably, the resin binder is a reactive resin that can undergo crosslinking with one or more components of the composition. In one embodiment of the invention, the resin binder is one that imparts aqueous developability to radiation sensitive compositions of the invention. Preferred resin binders include resins that contain polar functional groups, such as hydroxyl or carboxylate, that can impart aqueous developability. Further, the resin binder component is preferably employed in a composition in a concentration sufficient to render portions of a coating layer of the composition insoluble in aqueous processing chemicals.

The term “nonreactive resin” as used herein refers to a resin that does not substantially polymerize or cure with one or more of the components of the composition upon photoactivation of the same. Thus, upon curing of a composition, a nonreactive resin binder typically will be encapsulated within the polymerizable component(s) of the composition. Suitable nonreactive resins include, for example, acrylate polymers, preferably aqueous soluble acrylates such as acrylate polymers that contain carboxyl groups. The resin binder component suitably may comprise both nonreactive and reactive resin binders.

A reactive resin binder is suitably any of a variety of materials that will undergo photoinitiated crosslinking with one or more components of the composition. Thus suitable resins include those that contain one or more reactive moieties, for example a functionality that contains a reactive hydrogen. Phenolic resins are particularly suitable reactive resins. If the composition is a radiation sensitive or photoimageable composition, the phenolic resin is preferably employed in a concentration sufficient to render a coating layer of the composition developable with an aqueous solution or semi-aqueous solution. Suitable phenolic resins include, for example, phenol aldehyde condensates known in the art as the novolak resins, homo and copolymers of alkenyl phenols, partially hydrogenated novolak and poly(vinylphenol) resins, and homo and copolymers of N-hydroxyphenyl-maleimides.

Of the phenolic resins suitable as a reactive resin for the compositions of the invention, the phenol formaldehyde novolaks are preferred materials as the novolaks are able to form an aqueous developable, photoimageable coating composition. These resins are made following procedures known and disclosed in numerous publications such as DeForest, Photoresist Materials and Processes, McGraw-Hill Book Company, New York, Ch. 2, 1975; Moreau, Semiconductor Lithography Principles, Practices and Materials, Plenum Press, New York, Chs. 2 and 4, 1988; and Knop and Pilato, Phenolic Resins, Springer-Verlag, 1985, all said publications incorporated herein by reference for their teaching of making and using novolaks and other phenolic resins.

More particularly, novolak resins are the thermoplastic condensation product of a phenol and an aldehyde. Examples of suitable phenols for condensation with an aldehyde, especially formaldehyde, for the formation of novolak resins, include phenol; m-cresol; o-cresol; p-cresol; 2,4-xylenol; 2,5-xylenol; 3,4-xylenol; 3,5-xylenol; thymol and mixtures thereof. An acid catalyzed condensation reaction results in the formation of a suitable novolak resin which may vary in molecular weight from about 500 to 100,000 daltons. Preferred novolak resins include the cresol formaldehyde condensation products.

Another preferred reactive resin is a poly(vinylphenol) resin. Poly(vinylphenols) are thermoplastic materials that may be formed by block polymerization, emulsion polymerization or solution polymerization of corresponding monomers in the presence of a cationic catalyst. Vinylphenols used for production of poly(vinylphenol) resins may be prepared, for example, by hydrolysis of commercially available coumarins or substituted coumarins, followed by decarboxylation of the resulting hydroxy cinnamic acids. Useful vinyl phenols may also be prepared by dehydration of the corresponding hydroxy alkyl phenol or by decarboxylation of hydroxy cinnamic acids resulting from the reaction of substituted or non-substituted hydroxy benzaldehydes with malonic acid. Preferred poly(vinylphenol) resins prepared from such vinyl phenols have a molecular weight range of from about 2,000 to about 100,000 daltons. Procedures for the formation of poly(vinylphenol) resins also can be found in U.S. Pat. No. 4,439,516, incorporated herein by reference.

Another suitable class of reactive resin are polymers containing phenolic units and nonaromatic cyclic alcohol units analogous in structure to the novolak resins and poly(vinylphenol) resins. Such copolymer resins are described in European Published Patent Application No. 0 401 499 having a publication date of Dec. 12, 1990 and incorporated herein by reference.

An additional class of suitable phenolic reactive resins include homo and copolymers of N-hydroxyphenyl maleimides. Such materials are disclosed in European Published Application No. 0,255,989 beginning on page 2, line 45 and continuing to page 5, line 51, incorporated herein by reference.

The concentration of the resin component of the compositions of the invention may vary within relatively broad ranges, and in general the resin component is between about 10 and 60 or more weight percent of total solids of the compositions and more preferably, in an amount of from 15 to 30 weight percent of total solids. It has been found that as the concentration of the resin binder increases above 30 percent of total solids, the dielectric constant of a coating formed from the formulation increases above 3.0. In general a reactive resin is employed in a composition in a concentration of from about 0 (where only nonreactive resin(s) are employed) to 60 or more weight percent of the total solids of the composition. As used herein, the term total solids of a composition refers to all components of a composition other than a solvent carrier when such a solvent is used. When one of the components of the composition solvates the remaining components, then percent solids means all of the composition.

The second component of the compositions of the invention is an epoxidized polybutadiene that comprises one or more internal epoxide groups. The epoxidized polybutadiene suitably may also contain reactive groups in addition to one or more internal epoxy functionalities. For example, the butadiene may contain one or more vinyl groups, hydroxyl groups, carboxyl groups or pendant and/or terminal epoxy groups.

Particularly preferred epoxidized polybutadienes of the compositions of the invention are represented by the following formula (I):

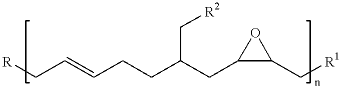

where R and R¹ are each independently selected from the group consisting of hydrogen, substituted and unsubstituted alkyl, substituted and unsubstituted aryl and a reactive group such as hydroxy, epoxy or an alkylene group, for example an alkylene group having from 2 to 10 carbon atoms, more typically having 2 carbon atoms. Suitable alkyl groups include those having from 1 to about 10 carbon atoms, more typically from 1 to about 6 carbon atoms. Phenyl is a suitable aryl group. The alkyl and aryl groups may be suitably substituted by, for example, aryl, alkyl, alkylene, halo, alkoxy or hydroxy. The group R² of formula (I) is preferably an alkylene carbon that forms a vinyl group with the carbon pendant to the butadiene backbone (i.e., R² is CH₂═), although a polybutadiene of formula (I) can be modified so that for one or more units of the butadiene the group R² is other than an alkylene carbon. For example such an alkylene group can be saturated so that R² is an alkyl carbon such as methyl. The value n of the above formula (I) is suitably 2 or greater, more preferably n is a value between about 10 and 25, still more preferably n is a value between about 20 and 25.

The polybutadiene of formula (I) above preferably has a molecular weight (weight average) of at least about 4000, preferably has a molecular weight of between about 4000 and 8000, still more preferably has a molecular weight between about 5000 and 6000.

A polybutadiene of formula (I) can be prepared in several ways. For example, a commercially available polybutadiene can be selectively oxidized to provide internal epoxide groups. Typically poly-1,3-butadienes are employed. Polybutadienes, including polybutadiene that with varying terminal groups including reactive groups such as hydroxy, are available from vendors such as BF Goodrich, Nisso, and Japan Synthetic Rubber. Under appropriate reaction conditions, an internal alkylene group will be more reactive to electrophilic substitution than a pendant vinyl group (i.e., where R² above is an alkylene carbon). Thus, an internal carbon-carbon double bond of the polybutadiene can be converted to a halohydrin by reaction with a halogen such as Cl₂ or Br₂ in the presence of water and a substantially non-nucleophilic solvent such as tetrahydrofuran or an aromatic solvent such as toluene or xylene. The epoxide can then be formed by alkaline treatment of the halohydrin. Suitable bases for formation of the internal epoxide via a halohydrin include alkoxides such as potassium t-butoxide and hydroxides such as sodium hydroxide. In formation of the halohydrin, a stoichiometric equivalent of halogen should be employed to limit addition to the more reactive disubstituted internal vinyl groups of the polybutadiene.

It is also believed that direct oxidation of the internal alkylene group of the polybutadiene can be employed to form a epoxidized polybutadiene of the invention. For example, a commercially available polybutadiene can be admixed in a suitable solvent and reacted with a suitable oxidant to provide the epoxide group. Suitable oxidants will include peracids such as perbenzoic acid, meta-chlorobenzoic acid, peracetic acid and trifluoroperacetic acid; alkaline oxidants such as sodium hydroxide and hydrogen peroxide (30 wt. % in water); or a substantially neutral oxidation of bubbling O₂ gas through the reaction mixture in the presence of a suitable catalyst such as Ag.

The internally epoxidized polybutadiene is preferably miscible with other component(s) of the composition both before and after curing. An epoxidized polybutadiene that is miscible with other components upon curing is believed to form a clear coating layer upon curing of the composition while a butadiene that is not miscible will provide an opaque cured coating layer, for example a milky-colored coating layer. While not wishing to be bound by theory, it is believed a clear, cured coating layer indicates the formation of a polymerized network comprising a substantially uniform distribution of the polymerizable components of the composition.

The concentration of the internally epoxidized butadiene component may vary within relatively broad ranges, and in general the internally epoxidized polybutadiene is employed in a concentration of at least about 10 weight percent of the total solids of a composition, more typically from about 10 to 60 or more weight percent of the total solids, and most preferably, in a range of from about 25 to 55 weight percent of total solids of a composition. The higher concentrations are preferred for compositions exhibiting a dielectric constant of 3 or less.

In addition to the resin binder and polybutadiene with internal epoxide groups, a preferred further component of the compositions of the invention is one or more materials capable of undergoing thermal or photoinduced crosslinking or both with one or more components of the composition. The crosslinking material is suitably a monomer, oligomer or polymer though a monomer or low molecular weight oligomer is preferred for solvent free compositions as liquid crosslinking agents may function as reactive solvating materials for the remaining components in the formulation.

Epoxy containing materials are one preferred group of crosslinkers, especially liquid monomeric and low molecular weight oligomeric epoxy containing materials. Epoxy containing materials are any organic compounds having one or more oxirane rings that are polymerizable by ring opening. Such materials, broadly called epoxides, include monomeric epoxy compounds, and oligomeric and polymeric epoxides that may be aliphatic, cycloaliphatic, aromatic or heterocyclic. Preferred materials generally, on average, have at least 2 polymerizable epoxy groups per molecule. The polymeric epoxides include linear polymers having terminal epoxy groups (e.g., diglycidyl ether of a polyoxyalkylene glycol), polymers having skeletal oxirane units (e.g., polybutadiene polyepoxide), and polymers having pendant epoxy groups (e.g., glycidyl methacrylate polymer of copolymer). The epoxides may be pure compounds but are generally mixtures containing one, two or more epoxy groups per molecule.

Useful epoxy-containing materials may vary from the preferred low molecular weight monomeric materials and oligomers to relatively high molecular weight polymers and may vary greatly in the nature of their backbone and substituent groups. For example, the backbone may be of any type and substituent groups may be any group free of any substituents reactive with an oxirane ring at room temperature. Illustrative of suitable substituents include halogens, ester groups, ethers, sulfonate groups, siloxane groups, nitro groups, phosphate groups, etc.

Further epoxy containing materials useful in the practice of this invention include glycidyl ethers. Examples are the glycidyl ethers of polyhydric phenols obtained by reacting a polyhydric phenol with an excess of chlorohydrin such as epichlorohydrin (e.g., the diglycidyl ether of 2,2-bis-(2,3-epoxy-propoxyphenol)propane). Further examples of epoxides of this type are described in U.S. Pat. No. 3,018,262, incorporated herein by reference.

There are many commercially available epoxy containing materials which can be used in the compositions of the invention. In particular, epoxides which are readily available include epichlorohydrin, glycidol, glycidylmethacrylate, the glycidyl ether of p-tertiarybutylphenol (e.g., those available under the trade name “Epi-Rez” 5014 from Celanese); diglycidyl ether of Bisphenol A (e.g., those available under the trade designations “Epon 828”, “Epon 1004” and “Epon 1010” from Shell Chemical Co.; and “DER-331”, “DER-332” and “DER-334” from Dow Chemical Co.), vinylcyclohexene dioxide (e.g., “ERL-4206” from Union Carbide Corp.), 3,4-epoxy-6-methyl-cyclohexylmethyl-3,4-epoxy-6-methylcyclohexene carboxylate (e.g., “ERL-4201” from Union Carbide Corp.), bis(3,4-epoxy-6-methylcyclohexylmethyl) adipate (e.g., “ERL-4289” from Union Carbide Corp.), bis(2,3-epoxycyclopentyl) ether (e.g., “ERL-0400” from Union Carbide Corp.), aliphatic epoxy modified with polypropylene glycol (e.g., “Erl-4050” and “ERL-4269” from Union Carbide Corp.), dipentene dioxide (e.g., “ERL-4269” from Union Carbide Corp.), flame retardant epoxy resins (e.g., “DER-580,” a brominated bisphenol type epoxy resin available from Dow Chemical Co.), 1,4-butanediol diglycidyl ether of phenolformaldehyde novolak (e.g., “DEN-431” and “DEN-438” from Dow Chemical Co.), and resorcinol diglycidyl ether (e.g., “Kopoxite” from Koppers Company, Inc.).

Another class of preferred crosslinkers are amine-based materials. A particularly preferred composition contains an amine-based thermal crosslinker which is capable of undergoing reaction with one or more components of the resin binder. Suitable amine-based thermal crosslinkers include melamine-formaldehyde resins, glycoluril-formaldehyde resins, and urea-based resins. Suitable melamine resins include the melamine resins manufactured by American cyanamid company of Wayne, N.J. and sold under the trade names Cymel 300, 301, 303, 350, 370, 380, 1116 and 1130. Suitable glycoluril resins include those sold by the American Cyanamid Company under the trade names of Cymel 1170, 1171, 1172. Suitable urea-based resins include those sold by the American Cyanamid Company under the trade names of Beetle 60, 65 and 80. A particularly preferred amine-based crosslinker is a benzoguanamine-based material, including the benzoguanamine resins sold by the American cyanamid Company under the trade names of Cymel 1123 and 1125. Additionally, combinations of the above amine-based crosslinkers will be suitable, including combinations that comprise a benzoguanamine-based material. In addition to the above resins available from the American Cyanamid Company, a large number of similar resins are commercially available from other suppliers. Additionally, such amine-based resins may be prepared by the reaction of acrylamide or methacrylamide copolymers with formaldehyde in an alcohol-containing solution, or alternatively by the copolymerization of N-alkoxymethyl acrylamide or methacrylamide with other suitable monomers. The crosslinker component of the compositions of the invention in general are used in an amount of between about 1 and 25 weight percent of total solids of the composition, more typically in amount of 5 to 15 weight percent of total solids of the composition. As noted above, the crosslinker compound of the composition is preferably used in combination with a phenol-based resin binder.

Of the above amine-based crosslinkers, the melamines are preferred. Particularly preferred are melamine formaldehyde resins, i.e., reaction products of melamine and formaldehyde. These resins are typically ethers such as trialkylol melamine and hexaalkylol melamine. The alkyl group may have from 1 to as many as 8 or more carbon atoms but is preferably methyl. Depending upon the reaction conditions and the concentration of formaldehyde, the methyl ethers may react with each other to form more complex units.

A compound that contains at least two vinyl ether groups is a suitable crosslinker for compositions that comprise a thermal or photoacid generator compound. Examples of compounds with at least two vinyl ether groups include divinyl ethers of aliphatic, cycloaliphatic, aromatic or araliphatic diols. Examples of such materials include divinyl ethers of aliphatic diols having from 1 to 12 carbon atoms, polyethylene glycols, propylene glycols, polybutylene glycols, dimethylcyclohexanes, etc. Specific examples include divinyl ethers of ethylene glycol, trimethylene-1,3-diol, diethylene glycol, triethylene glycol, dipropylene glycol, tripropylene glycol, resorcinol, Bisphenol A, etc.

A compound that contains one or more electrophilic multiple bonds is a suitable crosslinker at least for compositions that comprise a photobase generator compound. Examples of electrophilic multiple bonds include maleimides, alpha,beta-unsaturated ketones, esters, amides, nitriles and other alpha,beta-unsaturated electron-withdrawing groups. Typically the electrophilic multiple bond will be a carbon-carbon double bond activated by one or more electron-withdrawing substitutents, although activated acetylenes can also function as the electrophilic species. Preferred is a crosslinker that comprises two or more electrophilic multiple bonds. Particularly preferred are those active groups that comprise a carbon-carbon multiple bond that is stabilized by two electron-withdrawing substituents such as malonate esters or beta-keto esters or, preferably, maleimide groups. These Michael acceptors will undergo a base-initiated reaction with a suitable nucleophile. For example, in the compositions of the invention, the above described phenolic resin binders, epoxidized polybutadiene containing one or more internal epoxide groups, and/or the photoactivated base can undergo addition with these crosslinker materials that contain an electrophilic multiple bond.

Particularly preferred crosslinking materials that contain an electrophilic multiple bond include a crosslinker that contains one or more maleimide groups, and specifically preferred are bismaleimides of the following formula (II):

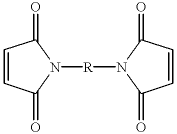

wherein R is selected from the group consisting of substituted or unsubstituted aryl, substituted or unsubstituted alkyl, or a group of the formula R¹-Ar-R²-Ar′-R³, where R¹, R² and R³ are independently selected from the group consisting of a substituted or unsubstituted alkyl, and Ar and Ar′ are each independently selected from the group consisting of substituted or unsubstituted aryl. Said substituted aryl and alkyl groups of the compounds of formula (II) are suitably substituted by one or more functionalities such as, for example, halogen, alkoxy (such as methoxy, ethoxy, etc.), aryl and alkyl. Said substituted and unsubstituted alkyl groups of formula (II) preferably have from 1 to 8 carbon atoms, more preferably 1 to 4 carbon atoms. Aryl groups are preferably phenyl. A specifically preferred compound of formula (II) is 1,1′-(methylenedi-1,4-phenylene)bismaleimide.

A number of suitable maleimides, including bismaleimides of formula (II) are commercially available. For example, suitable maleimides are available from Kennedy and Klim, Inc. of Little Silver, N.J. Other suitable maleimides can be readily synthesized by known procedures, for example by thermal or acidic condensation of maleic anhydride with a compound of a structure corresponding to R(NH²)², where R is as defined above in reference to formula (I). See, I. Varma, et al., Polymer News, vol. 12, 294-306 (1987), incorporated herein by reference.

Resins that contain electrophilic multiple bonds, or that contain both epoxy and electrophilic multiple bonds, also can be suitably employed as the crosslinking material in the compositions of the invention. Many suitable resins are commercially available, such as the bismaleimide resins available under the tradename Kerimid by Rhone-Poulenc, and Thermax MB-8000 available from Kennedy and Klim, Inc. Suitable maleimide resins are also described in the above incorporated article of I. Varma, et al., and in U.S. Pat. No. 4,987,264, incorporated herein by reference.

Another suitable crosslinker is an aromatic compound that contains one or more allyl substituents (i.e., the aromatic compound is substituted at one or more ring positions by the allylic carbon of an alkylene group). Suitable allyl aromatics include allyl phenyl compounds. More preferred is an allyl phenol compound. An allyl phenol curing agent can be a monomer, oligomer or polymer that contains one or more phenol units where the phenol units are substituted at one or more ring positions by an allylic carbon of an alkylene group. Typically the alkylene substituent(s) is propenyl, i.e., the phenol has one or more propenyl substitutents. Preferred allyl phenols include a polycondensate of phenol and hydroxybenzaldehyde and an allylhalide such as allylchloride. A number of suitable allyl phenols are commercially available, for example the allyl phenol sold under the trade name Thermax SH-150AR by Kennedy and Klim, Inc. (Little Silver, N.J.). Allyl phenyl compounds including allyl phenols and the use thereof are also described in above incorporated U.S. Pat. No. 4,987,264, and in H. Stenzenberger, British Polymer Journal, 20, 383-386 (1988), incorporated herein by reference. An allyl phenol crosslinker is preferably employed in combination with a crosslinker that contains an electrophilic multiple bond, for example a maleimide crosslinker.

A composition of the invention may suitably comprise only a single type of crosslinker, e.g., only a melamine crosslinker, or a composition may contain two or more different crosslinkers. The concentration of the one or more crosslinkers in a composition may vary within a relatively wide range. As will be appreciated to those skilled in the art, suitable concentrations will vary with factors such as crosslinker reactivity and specific application of the composition. In general, a suitable concentration of one or more crosslinkers is about 5 to 40 weight percent of total solids of the composition, preferably about 15 to 35 weight percent of total solids. The higher concentrations of the crosslinker are preferred where the crosslinker is liquid and functions as a cosolvent for the remaining constituents of the formulation.

The compositions of the invention typically further comprise a curing catalyst that may be a thermal or radiation sensitive component, or a combination of the two, that releases an acid or base to initiate the crosslinking reaction. The initiator will typically be an additional material in the composition, although the present invention includes compositions where the curing catalyst may be an integral part of another component of the composition, for example a resin binder that comprises pendant groups, or a binder that comprises an initiator group as a unit of the polymer chain.

The curing catalyst is selected from the group consisting of a compound capable of generating acid or base at elevated temperatures or upon exposure to activating radiation and is dependent upon whether the composition is to be a thermally cured material or a light sensitive composition.

Thermal curing catalysts are known in the art and typically comprise organic acids, for example, sulphonic acids. Th use of these acids are known to result in a fairly rapid cure at temperatures as low as room temperature and therefore are not added to the resin composition until shortly before the application of the system to a substrate. To make a one component system possible, the use of blocked curing catalysts from which acid is released at elevated temperatures is also known. Examples of such materials are amine salts of aromatic sulphonic acids such as dimethyloxazolidine salts. Another example of a blocked catalyst is a sulphonic acid abduct of an epoxy resin such as the glycidyl ethers of bisphenols and oligomers of such glycidyl ethers as suggested in U.S. Pat. No. 4,192,826 incorporated herein by reference. A preferred class of blocked sulphonic acid curing catalysts are disclosed in U.S. Pat. No. 4,839,427 incorporated herein by reference. These blocked catalysts comprise reaction products of a sulphonic acid and a glycidamide. Such products advantageously comprise at least one group per molecule represented by the formula:

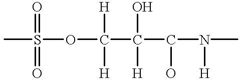

Specific examples of such materials may be found in the above referenced U.S. Pat. No. 4,839,427. Additional thermal curing catalysts may be found in U.S. Pat. No. 4,351,935 incorporated herein by reference. Examples of suitable blocked acids disclosed in said patent include benzil monoxime tosylate; furil monoxime tosylate; acetone oxime cetyl sulphonic acid ester; cyclopentanone oxime oleyl sulphonic acid ester; p-nitro acetophenone oxime tosylate; 2-hydroximinopropiophenone tosylate; α-oxininophenyl acetic acid ethyl ester tosylate; α-oximinocaproic acid ethyl ester tosylate; benzyl amido oxime tosylate; cyclopentanone oxime butyl sulphonic acid ester; cyclohexanone oximethyl sulphonic acid ester; p-chloro acetophenone oxime octyl sulphonic acid ester; di(2-naphthyl)-diketone monoxime ethyl sulphonic acid ester; propiophenone oxime tosylate; 1-(2-furyl)-1-butanone oxime tosylate; the dinonyl naphthalene disulphonic acid diester of benzil monoxime α-oximinobenzoyl acetic acid ethyl ester tosylate, and the like.

For light sensitive composition, a generally preferred catalyst or photoacid generator comprises the onium salts, preferably those with weakly nucleophilic anions. Such anions are the halogen complex anions of divalent to heptavalent metals or non-metals, for example, Sb, Sn, Fe, Bi, Al, Ga, In, Ti, Zr, Sc, D, Cr, Hf, and Cu as well as B, P, and As. Examples of suitable onium salts are diaryldiazonium salts and onium salts of group Va and b, Ia and b and I of the Periodic Table, for example, halonium salts, particularly aromatic iodonium and iodoxonium salts, quaternary ammonium, phosphonium and arsonium salts, aromatic sulfonium salts and sulfoxonium salts or selenonium salts. Examples of suitable onium salts can be found in U.S. Pat. Nos. 4,442,197; 4,603,101; and 4,624,912, all incorporated herein by reference.

Another suitable group of photoacid generating compounds are the iodonium salts. A preferred group of such salts are those resulting from the aryliodosotosylates and aryl ketones as disclosed, for example, in U.S. Pat. No. 4,683,317, incorporated herein by reference.

Of the photoacid generators, at least some non-ionic organic compounds should be suitable. Preferred non-ionic organic acid generators include halogenated non-ionic compounds such as, for example, 1,1-bis[p-chlorophenyl]-2,2,2-trichloroethane (DDT); 1,1-bis[p-methoxyphenyl]-2,2,2-trichloroethane (methoxychlorR); 1,2,5,6,9,10-hexabromocyclododecane; 1,10-dibromodecane; 1,1-bis[p-chlorophenyl]2,2-dichloroethane; 4,4′-dichloro-2-(trichloromethyl)benzhydrol, 1,1-bis(chlorophenyl)2-2,2-trichloroethanol (KelthaneR); hexachlorodimethylsulfone; 2-chloro-6-(trichloromethyl)pyridine; O,O-diethyl-O-(3,5,6-trichloro-2-pyridyl)phosphorothioate (DursbanR); 1,2,3,4,5,6-hexachlorocyclohexane; N(1,1-bis[p-chlorophenyl]-2,2,2-trichloroethylacetamide, tris [2,3-dibromopropyl] isocyanurate; 2,2-bis[p-chlorophenyl]-1,1-dichloroethylene; and their isomers, analogs, homologs and residual compounds. Of the above, tris[2,3-dibromopropyl] isocyanurate is particularly preferred. Suitable acid generators are also disclosed in European Published Patent Application No. 0232972, incorporated herein by reference. The term residual compounds as used above is intended to include closely related impurities or other modifications of the above halogenated organic compounds which result during their synthesis and which may be present in minor amounts in commercial products containing a major amount of the above compounds.

Suitable photobase generator compounds photodecompose (e.g., undergo photocleavage) upon exposure to activating radiation to provide a base. A base generator typically will be a neutral compound that generates base (e.g., an organic base such as an amine) upon photoactivation. It is believed that a variety of base generator compounds will be suitable for use in the compositions of the invention. Suitable base generators include organic compounds, for example, photoactive carbamates including benzyl carbamates and benzoin carbamates. Other suitable organic base generators include O-carbamoylhydroxylamines, O-carbamoyloximes, aromatic sulfonamides, alpha-lactones, amides such N-(2-arylethyenyl)amides, and amides. More specifically, suitable O-carbamoylhydroxylamines include compounds of the formula RR¹OC(═O)NR²R³ where R and R¹ are independently alkyl, aryl or acyl, R² is hydrogen or alkyl and R³ is alkyl or aryl. Suitable O-carbamoyloximes include compounds of the formula RR¹C(═N)OC(═O)NR²R³ where R and R¹ are independently hydrogen, alkyl or aryl, R² is alkyl or aryl and R³ is hydrogen or alkyl. Suitable sulfonamides include compounds of the formula ArS(═O)²NRR¹ where Ar is an aryl group, R is hydrogen or alkyl and R¹ is alkyl or aryl. Suitable alpha-lactams include compounds of the formula (III):

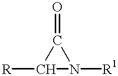

where R is alkyl or aryl and R¹ is alkyl or aryl. Suitable N-(2-arylethyenyl)amides include compounds of the structure RC(═O)N(R¹)CH═CHAr where Ar is an aryl group, R is alkyl or aryl and R¹ is alkyl. Other amides also will be suitable, for example formanilide and other aryl substituted amides. In the above described formulas, aryl is typically phenyl. As referred to in the above formulas, an alkyl group may be of a straight chain or branched configuration, or comprise a cyclic structure, and typically contains from 1 to 15 carbon atoms, more typically from 1 to 6 carbon atoms. An alkyl group is suitably either unsubstituted or substituted at one or more available positions. The substituents may be, for example, halo, aryl, or alkyl. Similarly, an aryl group also may be unsubstituted or substituted at one or more available positions by, for example, halo, aryl or alkyl.

Specifically preferred organic base generators include 2-hydroxy-2-phenylacetophenone N-cyclohexyl carbamate [i.e., (C₆H₅C(═O)CH(C₆H₅)OC(═O)NH C₆H₁₁], o-nitrobenzyl N-cyclohexyl carbamate [i.e., o-NO₂C₆H₅CH₂OC(═O)NHC₆H₁₁], N-cyclohexyl-2-naphthalene sulfonamide [i.e., C₁₀H₇SO₂NHC₆H₁₁], 3,5-dimethoxybenzyl N-cyclohexyl carbamate [i.e., (CH₃O)₂C₆H₅CH₂OC(═O)NHC₆H₁₁], N-cyclohexyl p-toluene sulfonamide [i.e., p-CH₃C₆H₅SO₂NHC₆H₁₁], and dibenzoin isophorone dicarbamate.

Metal coordination complexes that generate base upon exposure to activating radiation also will be suitable, such as the cobalt (III) complexes described in J. Coatings Tech., 62, no. 786, 63-67 (July 1990), incorporated herein by reference. The described photoactive materials include compounds of the formula Co(NH₂R)₅Xₙ⁺ where R is hydrogen, methyl or n-propyl, X is Cl⁻, Br⁻, I⁻ or other uninegative groups when n=2; and X is RNH₂ or H₂O when n=3, and a suitable counter ion chosen to impart the desired solubility. Suitable counter ions include, for example Cl⁻, Br⁻ or ClO₄⁻. Additionally, other metal coordination complexes that generate base upon exposure to activating radiation will be suitable photobase generators for use in the compositions of the invention.

Preparation of photobase generator compounds is known in the art. For example, suitable benzyl carbamates can be prepared by the reaction of a diisocyanate with a benzyl alcohol in the presence of a suitable catalyst. Thus dibenzoin isophorone dicarbamate is prepared by reaction of benzoin with isophorone diisocyanate in a suitable solvent, typically with heating, and in the presence of a suitable catalyst such as methyllithium. Suitable solvents include ether and tetrahydrofuran. Photoactivation of this base generator provides isophoronediamine. See J. Cameron et al., J. Am. Chem. Soc., vol. 113, no. 11, 4303-4313 (1991); J. Cameron et al., J. Polym. Mater. Sci. Eng., 64, 55 (1991); and J. Cameron, et al., J. Org. Chem., 55, 5919-5922 (1990), all of which are incorporated herein by reference for their teaching of preparation of photobase generators. Ortho-nitrobenzyl N-cyclohexylcarbamate can be prepared by reaction of cyclohexylisocyanate and 2-nitrobenzyl alcohol in a heated toluene solution until reaction completion. Thin layer chromatography can be employed to monitor progress of the reaction. Suitable reaction temperatures include temperatures at or about 110° C. See European Patent Application 0425 142 A2, publication date Feb. 5, 1991, incorporated herein by reference for its teaching of photobase generators and the preparation thereof. The synthesis of sulfonamides is well known and generally involves reaction of a sulfonyl chloride with an amine. Thus N-cyclohexyl p-toluene sulfonamide is prepared by reaction of p-toluenesulfonyl chloride and cyclohexyl amine in a suitable solvent with heating. Suitable solvents include for example tetrahydrofuran and toluene. A photoactive polymer may also be prepared and used in the compositions of the invention as the photobase generator component. For example, a polymer containing pendant photoactive carbamate groups can be employed. Such a polymer can be prepared by adding a tetrahydrofuran solution of a catalytic amount of 4-dimethylaminopyridine and triethylamine to a mixture of o-nitrobenzyloxycarbonyl chloride and p-aminostyrene. Upon reaction completion, the reaction product can be purified by standard means, for example flash column chromatography, to yield the o-nitrobenzyloxycarbonyl carbamate of p-aminostyrene. Other polymers will undergo similar reaction with a benzyl carbonyl chloride, for example copolymers such as poly(p-aminostyrene-co-styrene) and poly(p-aminostyrene-co-methyl methacrylate).

A photoacid or photobase generator should be present in a composition of the invention in an amount sufficient to enable development of a coating layer of the composition following exposure of the same to activating radiation and a post-exposure bake, if needed. More specifically, a photoacid generator or photobase generator is typically employed in a composition in a concentration of from about 1 to 15 weight percent of total solids of the composition, more typically from about 1 to 6 weight percent of total solids of the composition, although it should be clear that suitable concentrations of the photoactive component can vary with the particular agent that is employed.

Other additives may be optionally included in the compositions of the invention such as dyes, fillers, wettings agents, fire retardants and the like. A suitable filler is the product sold under the name TALC by Cyprus Chemical and a suitable dye is Orasol Blue available from Ciba-Geigy.

Photosensitizers constitute another preferred additive for purposes of the invention and are added to the composition in an amount sufficient to increase wavelength photosensitivity. Suitable photosensitizers include, for example, 2-ethyl-9,10-dimethoxyanthracene, 9,10-dichloroanthracene, 9,10-phenylanthracene, 1-chloroanthracene, 2-methylanthracene, 9-methylanthracene, 2-t-butylanthracene, anthracene, 1,2-benzanthracene, 1,2,3,4-dibenzanthracene, 1,2,5,6-dibenzanthracene, 1,2,7,8-dibenzanthracene, 9,10-dimethoxydimethylanthracene, and the like. Other suitable sensitizers include those disclosed in European Patent Application 0423446, incorporated herein by reference. Preferred sensitizers include 2-ethyl-9,10-dimethoxyanthracene, N-methylphenothiazine, and isopropylthioxanthone.

Fillers and dyes which may be present in large concentration such as, for example, in amounts of from 2 to 30 percent by weight of the total of the composition's solid components. Other optional additives such as wetting agents, gas release agents, leveling agents, etc. typically will be present in relatively low concentrations, for example less than about three weight percent of total solids of the composition.

In a preferred embodiment of the invention, to make a liquid coating composition, a liquid crosslinking agent is used in which the remaining components of the composition are soluble. The liquid crosslinking agent is used in an amount at least sufficient to dissolve the remaining components of the photoresist composition. Thus, the binder, the butadiene component having internal epoxide groups and the remaining components of the composition are dissolved in the crosslinking agent. Low molecular weight epoxy type crosslinking agents are especially suitable for this purpose. By use of the crosslinking agent capable of dissolving the remaining components of the system, a step of drying to evaporate a non-reactive solvent may be avoided. Moreover, a solvent recovery system would not be required. In a lesser preferred embodiment of the invention, a suitable solvent may be used to dissolve the remaining components of the composition. For example, suitable solvents include one or more of the glycol ethers such as ethylene glycol monomethyl ether, propylene glycol monomethyl ether, dipropylene glycol monomethyl ether; esters such as a methyl cellosolve acetate, ethyl cellosolve acetate, propylene glycol monomethyl ether acetate, dipropylene glycol monomethyl ether acetate and other solvents such as dibasic esters, propylene carbonate, gamma-butyro lactone and alcohols such as n-propanol.

The dry components are dissolved in the solubilizing crosslinking agent or in a solvent to form a liquid coating composition. The solids concentration will depend on several factors such as the method of application to a substrate. In general, the concentration of the solids in the solvent may vary from about 10 to 100 weight percent of the total weight of the coating composition. More specifically in the case of a curtain coating composition, the solids content may be in the range of between about 40 to 50 or more weight percent of the total weight of the composition.

The compositions of the invention may also be used to form a dry film photoresist laminate. A dry film resist laminate is typically produced by coating the liquid coating composition onto a suitable support such as a polyester film and then covering the resist film with a thin polymer film, for example a polyolefin film. The thin film can be peeled away prior to use and the solid resist layer is applied to a substrate surface by means of lamination. See, W. Deforest, Photoresist Materials and Processes, pp. 163-212 (McGraw Hill 1975), incorporated herein by reference.

Using a method for forming a printed circuit board for purposes of exemplification, a composition of the invention may be applied to a substrate having a pattern of conductive material disposed thereon. The substrate may be a copper laminate substrate prepared by the methods described in Coombs, Printed Circuits Handbook, McGraw-Hill, (3rd ed. 1988), incorporated herein by reference. Other suitable substrates include those prepared by laminating multilayer boards for the manufacture of printed circuit boards with vias (through-holes) and interconnections which may contain solder, as described in the above incorporated Printed Circuits Handbook, and semiconductor chips.

The compositions of the invention may be coated onto the substrate using conventional techniques including screen printing, curtain coating, roller coating, slot coating, spin coating, flood coating, electrostatic spray, spray coating, dip coating and as a dry film. As indicated above, the viscosity of the composition may be adjusted to meet the requirements for each method of application by adding additional solvent or solvating component for methods requiring low viscosity or thickening agents and fillers for methods requiring high viscosity.

After coating, if the composition utilizes a non-reactive liquid solvent, the liquid coating layer is dried to remove solvent. If the crosslinking agent functions as a solvent or solvating agent, the liquid composition may be directly cured by light or heat dependent upon the composition of the system, to form a solid coating.

In processes where the composition is photoimageable, the process of photo-reproducing a desired image to the photoimageable layer is well known in the art and involves exposing the layer to a source of activating radiation to initiate generation of acid or base in the exposed area. Suitable sources of activating radiation include an ultraviolet light source, electron beam, or x-rays. The photogenerated acid or base will initiate a reaction of one or more of the polymerizable components of the composition.

The coating layer of the composition is typically heated to induce or enhance crosslinking in exposed areas. This heating step would follow exposure when using a photoimageable composition. Exemplary post exposure bake conditions include heating to about 85 to 110° C. or greater for between about 10 to 40 minutes. Suitable heating times will vary with the particular post exposure bake temperature employed, with lower bake temperatures generally requiring longer heating periods.

By employing in a composition an effective concentration of an aqueous soluble resin that contains polar functional groups such as the above described phenolic resins in a photoimageable coating, the area of the coating not exposed to activating radiation is developable in aqueous solutions such as sodium hydroxide, sodium carbonate, potassium hydroxide, potassium carbonate, ethylene diamine and the like. Alternatively, the unexposed portions of a coating layer of the composition can be developed with a semi-aqueous solution. Suitable semi-aqueous solutions include alcoholic mixtures of alkali hydroxides wherein the alcohol is water miscible and present in the aqueous solution in concentrations of from about 2 to 20 percent by volume, preferably less than about 10 percent by volume.

The compositions of the invention will also be solvent developable in suitable organic developers including polar solvents such as alcohols and glycol ethers and mixtures thereof. Specific suitable organic developers include gamma-butryo lactone, propoxy propanol and N-methyl pyrrolidone.

Thermal curing after development may be conducted at temperatures ranging from about 120 to 180° C., preferably 120 to 140° C., for a period of time between about 20 and 120 minutes. The thermal cure hardens unreacted components, promotes flexibility of the coating layer and can enhance adhesion of the coating layer to the substrate. The coating layer also may be post cured using RF or microwave energy by methods well known in the coatings industry.

Many of the cured coatings of the invention will have a dielectric constant of 3 or less. This makes these compositions especially suitable for insulating layers for separating conductor patterns from one another.

Many of the thermally cured compositions of the invention will be highly useful as a soldermask, and will exhibit solder resistance and adhere well to copper circuitry. For example, compositions of the invention have withstood 550° F. solder flotation tests for 10 to 30 seconds without any blistering or other visible degradation of the thermally cured coating layer.

Additionally, the cured coating layers of some compositions of the invention have high glass transition temperatures, including glass transition temperatures of 125° C. and greater and Tgs of 150° C. and greater.

A crosslinked coating layer of a composition of the invention has the property of substantial flexibility and a dielectric constant of 3 or less. A more flexible crosslinked coating layer is highly advantageous because, for example, less care is required to prevent cracking or other degradation of the layer during subsequent processing steps. Cured coating layers of the compositions of the invention typically withstand 180° C. bend tests without cracking or any other degradation of the cured coating layer. Elongation testing of cured coating layers of the compositions provide values of 5 percent and greater elongation without any detection of degradation of the coating layer. In particular, the composition of Example 3, infra, exhibited an elongation value of 7 to 8 percent. It is believed that elongation values of a composition can be increased by increasing the concentration of the internally epoxidized polybutadiene component of a composition, and by reduction in the amounts of other composition constituents such as phenolic resin. As is known to those in the art, the term “elongation value” is the length of a sample stretches before breaking, expressed as a percentage of the sample length prior to stretching. For example, a one centimeter long sample which breaks after stretching to a 1.10 centimeter length would be said to have a 10 percent elongation value.

Thus, some of the compositions of the invention will be highly useful as flexible photoimageable cover coats in the manufacture of flexible circuits. A suitable process for the manufacture of a flexible circuit provides for etching a flexible base material to form a circuit layer by standard procedures (e.g., print and etch), stripping of photoresist, followed by cleaning of the base material surface. A composition of the invention is then applied to the cleaned surface. The composition may be suitably applied to the base material by a variety of coating means, for example roller coating or screen coating. The applied coating layer is then imaged and developed to provide openings, e.g., for solder pads. The coated base material can then be processed and used in accordance with known procedures. For such flex circuit applications, the photoimageable composition preferably comprises a brominated phenolic resin binder to provide a more fire retardant composition coating layer. As is clear to those in the art, a brominated phenolic resin is a resin where at least a portion of the resin phenolic units are bromo substituted at one or more available ring positions.

Compositions of the invention will also be useful as dielectric innerlayers for multilayer printed circuit boards that are produced by a sequential layering process as described above and in U.S. Pat. No. 4,902,610. For example, a composition of the invention can be coated over a first circuit layer and then, if the coating is photoimageable, the coating layer imaged to provide openings that define interconnections, and then one or more other board layers sequentially formed over the imaged composition layer to form a circuit board having two or more layers of circuitry. The first circuit layer will be in electrical connection with other circuit layer(s) of the board by means of the imaged openings of the coating layer. A typical application of a dielectric innerlayer would comprise application of a two mil layer of a photoimageable composition of the invention over a pre-cleaned circuitry substrate having 6-mil wide conductors; formation of 3-mil diameter via apertures in the coating layer by means of exposure and developed as discussed above; and post-development curing of the photodielectric layer. The via apertures will be located at predetermined sites within the width of the underlying conductors. Thus the apertures can be formed simultaneously rather than individually drilling holes as is done in conventional multilayer board manufacturing processes. Further, the apertures can be significantly smaller in such a sequential fabrication process than can be done by drilling. For example, photoformed via apertures can be provided with diameters as small as 2 mil. Additionally, via apertures of any shape can be imaged and developed, including squares and slots. The vias can then be plated with electroless copper at the same time as the second layer of circuitry conductors are plated.

Other applications of the compositions of the invention include use as an outerlayer for surface pad mounts where, the pads interconnected to the underlying circuit layer of a printed circuit board by means of electrolessly plated photoformed vias. The compositions of the invention can also be used as a resist in full-build additive plating processes such as printed circuit manufacturing processes. For a full-build additive circuit manufacturing process, it is highly desirable to employ a permanent photoimageable dielectric mask as insulation between the electrolessly plated circuitry conductors. Further, the photoimageable mask should be capable of fine line resolution, aqueous developable and serve as a resist to full build high pH electroless copper plating solutions for many hours at elevated temperatures without unwanted extraneous copper deposition on the mask.

The following non-limiting Examples are illustrative of the invention.

### EXAMPLES 1 to 17

### Solvent Based Photoimageable Compositions

Seventeen different photoimageable compositions of the invention were prepared by admixing the components in the amounts as specified in the below Table. Amounts listed in the Table grid are expressed in parts by weight based on the total weight (including solvent) of the specified composition.

TABLE

| Composition of | Resin | Amount | Amount Epoxy | Amount | Amount | Amount |
|---|---|---|---|---|---|---|
| Example No. | Binder | Resin Binder | Butadiene | Melamine | Epoxy Resin | Photoinitiator |
| 1 | AA | 50 | 30 | 10 | 10 | 4 |
| 2 | AB | 45 | 35 | 10 | 10 | 4 |
| 3 | AC | 45 | 35 | 10 | 10 | 4 |
| 4 | AD | 50 | 30 | 10 | 10 | 4 |
| 5 | AE | 60 | 30 | 10 | — | 4 |
| 6 | AF | 50 | 40 | 10 | — | 4 |
| 7 | AC | 45 | 35 | 20 | — | 4 |
| 8 | AC | 60 | 30 | 10 | — | 4 |
| 9 | AC | 45 | 25 | 10 | 20 | 4 |
| 10 | AC | 45 | 35 | 10 | 10 | 4 |
| 11 | AC | 30 | 40 | 15 | 15 | 4 |
| 12 | AC | 57 | 15 | 10 | 18 | 4 |
| 13 | AC | 45 | 45 | 10 | — | 4 |
| 14 | AC | 40 | 50 | 10 | — | 4 |
| 15 | AC | 35 | 55 | 10 | — | 4 |
| 16 | AB | 25 | 30 | 10 | 10 | 4 |
| | AC | 25 | | | | |
| 17 | AC | 25 | 40 | 10 | — | 4 |
| | AF | 25 | | | | |

In addition to the components listed in the above Table, 2-ethyl-9,10-dimethoxyanthracene was employed as a photosensitizer in each of the compositions at a concentration of 1 part by weight based on the total weight of the specified composition.

The solvent used in each of the compositions was propylene glycol monomethyl ether acetate. Each of the compositions was formulated at about 42 percent by weight solids.

In the above Table, the following designations represent the following materials:

Resin Binders:

AA is a cresol-formaldehyde novolak having a molecular weight (weight average) of about 11,000.

AB is a m-cresol-formaldehyde having a melting point of about 145-155O and a molecular weight (weight average) of about 5500.

AC is a poly(vinylphenol) resin having a molecular weight (weight average) of about 5200.

AD is a poly(vinylphenol) resin having a molecular weight (weight average) of about 13700.

AE is a partially hydrogenated polyvinyl phenol resin containing phenolic and nonaromatic cyclic alcohol units and having a molecular weight (weight average) of about 5200.

AF is a polyacrylate formed by free radical polymerization of the following monomer mixture: about 12 parts by weight methacrylic acid, 8 parts by weight hydroxyl-ethylmethyl acrylate, 40 parts by weight butyl acrylate and 49 parts by weight methylmethacrylate.

The epoxy butadiene used in the compositions was an epoxidized polybutadiene obtained from Atochem North America, Inc. (Philadelphia, Pa.) under the tradename Poly bd 605 Resin and was a compound of formula (I) as defined above where R and R1 are both hydroxyl and R2 is an alkylene carbon that forms a pendant vinyl group. The polybutadiene had a molecular weight of about 5500 and an epoxy equivalent weight of about 260.

The melamine used in the compositions was a melamine-formaldehyde resin available from American Cyanamid under the trade name Cymel 303.

Except for the composition of Example 10, the epoxy resin was aromatic bisphenol epoxy resin available from Shell Chemical Co. under the trade name EPON 828. In the composition of Example 10, an epoxy novolak resin was employed, available from Ciba-Geigy under the tradename EPN-1139.

The photoinitiator used the compositions was the acid generator triarylsulfonium antimonate.

### EXAMPLE 18

### Formation of Relief Images

Each of the compositions of Examples 1-17 above were separately applied by Meier rod to a dry film thickness of about 22 to 28 microns on the copper surface of a one-sided copper-clad plastic laminate. Prior to application of a composition, the copper surface of the substrate had been scrubbed clean with pumice-based Scrub Cleaner 28 (available from the Shipley Co.), followed by water rinsing and drying of the scrubbed copper surface. The applied liquid coatings were dried for 45 minutes in a 90° C. fresh air circulating convection oven. The coated parts were then each exposed with a Mimir light source using a 1000 mJ/cm2 exposure dose, except for the part coated with the composition of Example 5 which required a higher exposure dose. The compositions of each of Examples 1-17 were subject to broad band exposure. All the parts were contact printed, except for parts coated with compositions of Examples 11 and 15 which were exposed off-contact. Following exposure the coated parts were post exposure baked for 15 minutes at 100° C. After cooling, the exposed coating layers were immersion developed at about 30-35° C. with Developer 303A (aqueous sodium hydroxide developer available from the Shipley Co.) except for the part coated with the composition of Example 6 which was developed with a one percent aqueous sodium carbonate solution. For each of the coated parts, the aqueous development completely removed the composition from unexposed areas of the substrate to provide good quality negative tone relief images. Resolution of 1 mil wide lines and spaces was typically achieved for each of the compositions. The developed coating layers were then cured at either 120° C. or 140° C. for 60 minutes.

### EXAMPLES 19 to 21

### Flexibility Testing and Flexible Circuit Applications

### EXAMPLE 19

Copper laminate parts with developed and cured coating layers of each of the compositions of Examples 1-17 were prepared as described in Example 18 above. Each part was then subjected to the following flexibility test: A 0.5 inch wide coated copper laminate strip was sheared from the part. In each case, the sheared edges of the 0.5 inch wide strip were clean and free of any noticeable cracking of the cured composition. The underlying plastic laminate strip was then fractured, but without fracture to the copper layer or overcoated cured composition. The overcoated copper layer was then pulled 180° back on itself. For each of the parts, no cracking or other degradation of the composition coating layer was observed.

### EXAMPLE 20

### Photoimaging

The compositions of Examples 13-15 were each coated onto a flexible circuit base material and exposed, developed and cured as described in Example 18 above. These coated substrates were then wrapped 180° C. around a one quarter inch diameter mandrel. For each of the coated substrates, adhesion of the cured composition to the underlying flexible copper circuit base layer was excellent and no evidence of cracking or crazing of the composition layer as a result of the bend test was observed.

### EXAMPLE 21

### Coating

Adhesiveless copper-clad films of the polyimide sold under the tradename Kapton and the polyester sold under the tradename Mylar were etched to remove the copper. The composition of Example 1 above was applied to the Kapton film, and the composition of Example 13 above was applied to the Mylar film to provide film thickness of about 20-25 microns. The coated films were exposed, developed and cured as generally described in Example 18 above. After curing, the patterned coating layers had excellent adhesion to the film substrates and withstood a 180° bend test in both directions without any cracking.

### EXAMPLE 22

### Solder Resistance

The compositions of Examples 2, 3, 9, 13, 14 and 15 were each coated onto separate copper-clad plastic laminates and dried, exposed, enhancement baked, developed and cured by the procedures described in Example 18 above. The cured composition layers were then cut in a cross hatch pattern with a razor blade. The thus cut coating layers were then subjected to a 550° F. solder flotation test for ten seconds. No solder wicking was observed, even in the cross hatch areas where copper metal had been exposed and where soldering occurred. The coating layers showed no blistering or any other visible effects as a result of the solder flotation test.

A second set of copper-clad laminates were prepared having developed, cured coating layers of the compositions of Examples 2, 3, 9, 13, 14 and 15. These coated parts were subjected to a 550° C. solder flotation test for 30 seconds. The coating layers showed no blistering or any other visible effects as a result of the solder flotation test.

### EXAMPLE 23

### Full-build Additive Plating

One ounce copper clad epoxy laminates substrates were etched to thereby bare a roughened epoxy surface with micropores. The substrates were then immersed in the electroless catalyst solution CATAPOSIT 44 (available from the Shipley Co.) for five minutes followed by water rinsing and drying of the treated substrates. By means of a #44 Meier rod, the compositions of Examples 3 and 13 were applied to separate catalyzed copper clad substrates, dried, image exposed, enhancement post exposure baked for 15 minutes at 100° C., developed with 303A Developer (Shipley Co.), rinsed, dried and cured for 60 minutes at 140° C. to provide 1.1 mil deep trenches exposing the catalyzed epoxy in a circuitry pattern. The parts were then immersed in Accelerator 19A (available from Shipley Co.) for five minutes to accelerate the palladium/tin plating catalyst, water rinsed, and then placed in a full build electroless copper bath until a 1 mil thickness (about 25 microns) had been deposited in the noted trenches. The plating bath was operated at about 70° C. and deposited copper at about 2.2 microns per hour. No evidence of unwanted extraneous copper or of any attack of copper on the composition relief images were observed. The produced circuitry lines were contained within the thickness of the applied permanent masks.

### EXAMPLE 24

### Moisture Insulation Testing

The compositions of Examples 2, 3, 9, and 13 were each coated onto separate copper-clad plastic laminates and dried, exposed, enhancement baked, developed and cured by the procedures described in Example 18 above. The coated copper-clad laminates were then subjected to IPC Test No. SM840B which provides for exposure in a high humidity chamber (90% r.h.) at a temperature of about 25-65° C. with 7 day cycling. The IPC Test specifies a acceptability at 0.5×10-8. Each of the tested composition coating layers exceeded a value of 0.1×10-10.

### EXAMPLE 25 to 35

### 100% Solids Compositions

Eleven different one hundred percent solids compositions of the invention were prepared by admixing the components in the amounts as specified in the below Table. Amounts listed in the Table grid are expressed in parts by weight based on the total weight of the specified composition components.

| Example | Solvating | Epoxy | Cross- | | | |
|---|---|---|---|---|---|---|
| No.¹ | Agent | butadiene | linker 1 | Crosslinker 2 | TAG | PAG |
| 25 | 33 | 33 | 10 | 20 | 4 | 0 |
| 26 | 33 | 33 | 10 | 20 | 0 | 4 |
| 27 | 50 | 23 | 10 | 30 | 4 | 0 |
| 28 | 50 | 23 | 10 | 30 | 0 | 4 |
| 29 | 20 | 43 | 10 | 20 | 4 | 0 |
| 30 | 20 | 43 | 10 | 20 | 0 | 4 |
| 31 | 23 | 23 | 30 | 20 | 4 | 0 |
| 32 | 23 | 23 | 30 | 20 | 0 | 4 |
| 33 | 23 | 50 | 10 | 13 | 4 | 0 |
| 34 | 23 | 50 | 10 | 13 | 0 | 4 |
| 35 | 0 | 48 | 48 | 0 | 4 | 0 |

¹In the table, the materials used are as follows:
Reactive resin - cresol novolak resin
Epoxidized butadiene - 1,4-butane diglycidyl ether
Crosslinking agent - melamine formaldehyde resin sold under the trade name Cymel 303
Thermal acid generator (TAG) - blocked naphalene disulphonic acid sold under the trade name Nacure 5225
Photoacid generator (PAG) - sulfonium complex onium salt sold under the trade name CD1010.

The composition of Example 25 was coated in a 2 mil thickness onto a prepatterned innerlayer board with 3 mil lines and spaces. The panel was placed in a 170° C. oven for 1 hour. The coating over the panel cured and was then ready for further processing such as laser drilling of vias.

The composition of Example 26 was coated in a 2 mil thickness onto a prepatterned innerlayer board with 3 mil lines and spaces. The panel was subjected to a blanket exposure of 1 J then placed in a 170° C. oven for 1 hour. The coating over the panel cured and was then ready for further processing such as laser drilling of vias.

### EXAMPLES 36-46

The compositions of Examples 25 to 35 were reformulated with the addition of 40 weight percent propylene glycol monomethyl ether acetate used as a solvent for the formulation.

The composition of Example 36 was coated in a 5 mil thickness onto a prepatterned innerlayer board with 3 mil lines and spaces. The panel cured was placed in a 90° C. drying oven for 30 min, then placed into a 170° C. oven for 1 hour. The coating over the panel cured and was then ready for further processing such as laser drilling of vias.

The composition of example 37 was coated in a 5 mil thickness onto a prepatterned innerlayer board with 3 mil lines and spaces. The panel was subjected to a blanket exposure of 1 J then placed in a 170° C. oven for 1 hour. The coating over the panel cured and was then ready for further processing such as laser drilling of vias.

The compositions of examples 25 to 35 are preferred over those of Examples 36 to 46 as they are solvent free and do not require the drying step to remove solvent.

The foregoing description of the invention is merely illustrative thereof, and it is understood that variations and modifications can be effected without departing from the scope or spirit of the inventions as set forth in the following claims.

What is claimed is:

1. A coating composition comprising a resin binder, a polybutadiene that comprises one or more internal epoxide groups, and a crosslinking agent, said coating composition being capable of providing a dried and cured coating that is flexible and has a dielectric constant of 3 or less.

2. The composition of claim 1 where the crosslinking agent is a solvent for the remaining components of the composition.

3. The composition of claim 2 essentially free of a solvent that is non-reactive with the remaining components of the composition.

4. The composition of claim 2 where the crosslinking agent comprises one or more materials selected from the group consisting of an amine-based compound, a compound containing one or more epoxy groups, a compound containing one or more vinyl ether groups, a compound containing one or more electrophilic multiple bonds, and an aromatic compound containing one or more allyl substituents.

5. The composition of claim 4 where the crosslinking agent is a compound containing one or more epoxy groups.

6. The composition of claim 4 where the crosslinking agent is a monomeric or low molecular weight oligomeric compound containing epoxy groups.

7. The composition of claim 2 where the polybutadiene is a compound of the following formula (I): 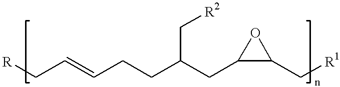
where R and R¹ are each independently selected from the group consisting of hydrogen, substituted and unsubstituted alkyl, substituted and unsubstituted aryl, epoxy, hydroxy and alkylene; R² is selected from the group consisting of alkylene and alkyl; and n is an integer equal to 2 or greater.

8. The composition of claim 7 where the polybutadiene has a molecular weight of at least about 4,000.

9. The composition of claim 8 where the polybutadiene has a molecular weight of from about 4,000 to 8,000.

10. The composition of claim 2 where the polybutadiene is present in a concentration sufficient for a dried and cured coating formed from the composition to have a dielectric constant of 3 or less.

11. The composition of claim 10 where the dielectric constant is 2.5 or less.

12. The composition of claim 10 where the concentration of the polybutadiene is at least 10 percent by weight of total solids.

13. The composition of claim 10 where the concentration ranges between 10 and 60 percent by weight of total solids.

14. The composition of claim 10 where the concentration ranges between 25 and 55 percent by weight of total solids.

15. The composition of claim 10 where the concentration of the resin binder does not exceed 30 percent by weight of total solids.

16. The composition of claim 15 where the concentration of the resin binder varies between 15 and 30 percent by weight of total solids.

17. The composition of claim 2 where the phenolic resin binder is selected from the group consisting of (1) a novolak resin, (2) a poly(vinylphenol) resin, (3) a resin containing phenolic units and cyclic alcohol units; and(4) a brominated phenolic resin.

18. The composition of claim 17 where the resin binder comprises a phenolic resin.

19. The composition of claim 2 containing a curing catalyst.

20. The composition of claim 19 where the curing catalyst is a member selected from the group consisting of thermal acid generators, photoacid generators, and mixtures thereof.

21. The composition of claim 19 where the curing catalyst is a thermal acid generator.

22. The composition of claim 19 where the curing catalyst is a photoactive generator.

23. The composition of claim 19 where a dried and imaged coating formed from the composition is developable in an aqueous solution.

24. A process for forming an imaged coating layer on a substrate, comprising:
(a) applying a coating composition on the substrate, the composition comprising a resin binder, a polybutadiene that comprises one or more internal epoxide groups, a crosslinking agent, and a curing catalyst, said coating composition being capable of providing a dried coating that is flexible and has a dielectric constant of 3 or less; and
(b) curing the coating at an elevated temperature.

25. The process of claim 24 where the crosslinking agent is a solvent for the remaining components of the composition.

26. The process of claim 25 where the coating composition is essentially free of a solvent that is non-reactive with the remaining components of the composition.

27. The process of claim 24 characterized by the absence of a step of baking to remove solvent.

28. The process of claim 25 where the crosslinking agent is a compound containing one or more epoxy groups.

29. The process of claim 28 where the crosslinking agent is a monomeric or low molecular weight oligomeric compound containing epoxy groups.

30. The process of claim 25 where the polybutadiene is a compound of the following formula (I): 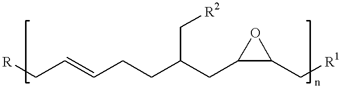
where R and R¹ are each independently selected from the group consisting of hydrogen, substituted and unsubstituted alkyl, substituted and unsubstituted aryl, epoxy, hydroxy and alkylene; R² is selected from the group consisting of alkylene and alkyl; and n is an integer equal to 2 or greater.

31. The process of claim 30 where the polybutadiene has a molecular weight of at least about 4,000.

32. The process of claim 25 where the polybutadiene is present in a concentration sufficient for a dried and cured coating formed from the composition to have a dielectric constant of 3 or less.

33. The process of claim 31 where the dielectric constant is 2.5 or less.

36. The process of claim 28 where the concentration of the polybutadiene is at least 10 percent by weight of total solids.

37. The process of claim 25 where the concentration ranges between 10 and 60 percent by weight of total solids.

38. The process of claim 25 where the concentration ranges between 25 and 55 percent by weight of total solids.

39. The process of claim 25 where the concentration of the resin binder does not exceed 30 percent by weight of total solids.

40. The process of claim 39 where the concentration of the resin binder varies between 15 and 30 percent by weight of total solids.

41. The process of claim 25 where the phenolic resin binder is selected from the group consisting of (1) a novolak resin, (2) a poly(vinylphenol) resin, (3) a resin containing phenolic units and cyclic alcohol units; and(4) a brominated phenolic resin.

42. The process of claim 41 where the resin binder comprises a phenolic resin.

43. The composition of claim 24 containing a curing catalyst.

44. The composition of claim 43 where the curing catalyst is a member selected from the group consisting of thermal acid generators, photoacid generators, and mixtures thereof.

45. The composition of claim 43 where the curing catalyst is a thermal acid generator.

46. The composition of claim 43 where the curing catalyst is a photoactive generator.

47. The process of claim 24 where the substrate is selected from the group consisting of a printed circuit board substrate, a flexible circuit base material, a multichip module, a semiconductor chip, and a hybrid circuit substrate.

48. The process of claim 47 where the substrate is one layer of a multilayer circuit board.

49. A cured and crosslinked dielectric material comprising a polymeric mixture of a phenolic resin and a polybutadiene that comprises one or more internal epoxide groups, said dielectric material having a dielectric constant of 3 or less and an elongation value of at least 5 percent.

50. The dielectric material of claim 49 where crosslinking is caused by a crosslinking agent selected from the group consisting of an amine-based compound, a compound containing one or more epoxy groups, a compound containing one or more vinyl ether groups, a compound containing one or more electrophilic multiple bonds, and an aromatic compound containing one or more allyl substituents.

51. The dielectric material of claim 50 where the crosslinking agent is a compound containing one or more epoxy groups.

52. The dielectric material of claim 50 where the crosslinking agent is a monomeric or low molecular weight oligomeric compound containing epoxy groups.

53. The dielectric material of claim 49 where the polybutadiene has a molecular weight of at least about 4,000.

54. The dielectric material of claim 49 where the polybutadiene is present in a concentration sufficient for a dried and cured coating formed from the composition to have a dielectric constant of 3 or less.

55. The dielectric material of claim 49 where the dielectric constant is 2.5 or less.

56. The dielectric material of claim 49 where the concentration of the polybutadiene is at least 10 percent by weight of total solids.

57. The dielectric material of claim 49 where the concentration ranges between 10 and 60 percent by weight of total solids.

58. The dielectric material of claim 49 where the concentration ranges between 25 and 55 percent by weight of total solids.

59. The dielectric material of claim 49 where the concentration of the resin binder does not exceed 30 percent by weight of total solids.

60. The dielectric material of claim 49 where the concentration of the resin binder varies between 15 and 30 percent by weight of total solids.

61. The dielectric material of claim 49 where the phenolic resin binder is selected from the group consisting of (1) a novolak resin, (2) a poly(vinylphenol) resin, (3) a resin containing phenolic units and cyclic alcohol units; and(4) a brominated phenolic resin.

62. The dielectric material of claim 61 where the resin binder comprises a phenolic resin.
